(19) United States
(12) Patent Application Publication
(10) Pub. No.: US 2025/0273567 A1
(43) Pub. Date: Aug. 28, 2025

(54) SEMICONDUCTOR INTEGRATED CIRCUIT DEVICE

(71) Applicant: Socionext Inc., Kanagawa (JP)

(72) Inventor: Hideyuki KOMURO, Yokohama-shi (JP)

(21) Appl. No.: 19/206,640

(22) Filed: May 13, 2025

Related U.S. Application Data
(63) Continuation of application No. PCT/JP2023/043310, filed on Dec. 4, 2023.

(30) Foreign Application Priority Data
Dec. 22, 2022 (JP) 2022-205841

(51) Int. Cl. H01L 23/528; H01L 23/522; H10D 30/00; H10D 30/43; H10D 62/10; H10D 84/83

(52) U.S. Cl. CPC H01L 23/528; H01L 23/5226; H01L 23/5283; H10D 30/43; H10D 30/502; H10D 62/121; H10D 84/832

(57) ABSTRACT

In a semiconductor integrated circuit device, a standard cell includes: an active region forming the channel, source, and drain of a transistor; and a power line formed on the back side of the transistor. A first region in the active region is connected to the power line through a via. A nanosheet contiguous with the active region is formed on a cell boundary. A gate interconnect, which is orthogonal to the nanosheet in planar view, is electrically connected to the first region.

### CROSS-REFERENCE TO RELATED APPLICATIONS

This is a continuation of International Application No. PCT/JP2023/043310 filed on Dec. 4, 2023, which claims priority to Japanese Patent Application No. 2022-205841 filed on Dec. 22, 2022. The entire disclosures of these applications are incorporated by reference herein.

### BACKGROUND

The present disclosure relates to a semiconductor integrated circuit device.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, of which the transistor structure has changed from the conventional planar structure to a three-dimensional structure, have been vigorously studied. A nanosheet field effect transistor (FET) is one example of such three-dimensional transistors.

US Patent Application Publication No. 2021/375853 discloses, for further higher integration, a technique of providing interconnects on the back of a substrate right under transistors and connecting the sources/drains of the transistors to the interconnects.

In a semiconductor integrated circuit device having nanosheet FETs, for improving manufacturing precision, reducing manufacturing variations, and improving yield, it is preferable to form a plurality of nanosheet FETs without discontinuities. To achieve this, nanosheet FETs need be formed even in regions between adjacent standard cells. However, in this configuration, it is necessary to ensure that nanosheet FETs formed between adjacent standard cells will have no influence on the circuit operation.

An objective of the present disclosure is presenting a layout structure in which nanosheet FETs having no influence on the circuit operation are formed between adjacent standard cells in a semiconductor integrated circuit device having interconnects provided right under transistors.

### SUMMARY

According to the first mode of the disclosure, a semiconductor integrated circuit device includes first and second standard cells placed adjacently in a first direction, wherein the first standard cell includes a first active region forming a channel, source, and drain of a first transistor of a first conductivity type, including a nanosheet extending in the first direction as the channel, a first power line supplying a first power supply voltage, formed on the back side of the first transistor, extending in the first direction, and having an overlap with the first active region in planar view, and a first via formed at a position where a first region forming a source or a drain in the first active region and the first power line overlap each other, to connect the first region and the first power line, a first nanosheet extending in the first direction and contiguous with the first active region and a first gate interconnect extending in a second direction perpendicular to the first direction and orthogonal to the first nanosheet in planar view are formed on a boundary between the first standard cell and the second standard cell, and the first gate interconnect is electrically connected to the first region.

According to the above mode, first and second standard cells are placed adjacently in the first direction. The first standard cell includes: a first active region forming the channel, source, and drain of a transistor; and a first power line formed on the back side of the transistor. A first region in the first active region is connected to the first power line through a first via. A first nanosheet contiguous with the first active region is formed on the boundary between the first and second standard cells. With this, since the active region is continuous over a plurality of standard cells, a plurality of nanosheet transistors can be formed without discontinuities. A first gate interconnect orthogonal to the first nanosheet in planar view is electrically connected to the first region, to be supplied with the first power supply voltage. Thus, the transistor constituted by the first gate interconnect and the first nanosheet is an off transistor, having no influence on the circuit operation of the semiconductor integrated circuit device.

According to the present disclosure, in a semiconductor integrated circuit device having interconnects provided right under transistors, nanosheet FETs having no influence on the circuit operation can be formed between adjacent standard cells.

### BRIEF DESCRIPTION OF THE DRAWINGS

FIG. 1 is a plan view showing an example of the layout structure of an inverter cell included in a semiconductor integrated circuit device according to an embodiment.

FIGS. 2A and 2B are cross-sectional views of the inverter cell of FIG. 1 taken horizontally in planar view.

FIGS. 3A and 3B are cross-sectional views of the inverter cell of FIG. 1 taken vertically in planar view.

FIG. 4 is a circuit diagram of the inverter cell shown in FIGS. 1, 2A-2B, and 3A-3B.

FIG. 5 is a cross-sectional view showing another configuration example of the inverter cell of FIG. 1.

FIGS. 6A and 6B show another configuration example of the semiconductor integrated circuit device according to the embodiment.

FIGS. 7A and 7B are plan views showing examples of the layout structures of cells included in the semiconductor integrated circuit device according to the embodiment, where FIG. 7A shows a 2-input NAND cell and FIG. 7B shows a 2-input NOR cell.

FIG. 8A is a circuit diagram of the 2-input NAND cell, and FIG. 8B is a circuit diagram of the 2-input NOR cell.

FIGS. 9A and 9B are plan views showing alterations of the configurations of FIGS. 7A and 7B, where FIG. 9A shows a 2-input NAND cell and FIG. 9B shows a 2-input NOR cell.

FIGS. 10A and 10B are plan views showing examples of the layout structures of buffer cells included in the semiconductor integrated circuit device according to the embodiment.

FIG. 11 is a circuit diagram of the buffer cells.

FIGS. 12A and 12B are plan views showing examples of the layout structures of double-height cells included in the semiconductor integrated circuit device according to the embodiment, where FIG. 12A shows an inverter cell and FIG. 12B shows a buffer cell.

FIG. 13 shows an alteration of the configuration of the inverter cell of FIG. 1.

FIGS. 14A to 14C are plan views showing examples of the layout structures of filler cells included in the semiconductor integrated circuit device according to the embodiment.

FIG. 15 is a plan view showing an example of the block layout of the semiconductor integrated circuit device according to the embodiment.

### DETAILED DESCRIPTION

An embodiment of the present disclosure will be described hereinafter with reference to the accompanying drawings. In the following embodiment, it is assumed that the semiconductor integrated circuit device includes a plurality of standard cells (hereinafter simply called cells as appropriate), and at least some of the standard cells include nanosheet field effect transistors (FETs). The nanosheet FET is a FET using a thin sheet (nanosheet) through which a current flows. Such a nanosheet is formed of silicon, for example. Note however that, in the present disclosure, the transistors included in the standard cells are not limited to nanosheet FETs.

As used herein, “VDD” and “VSS” refer to the power supply voltages or the power supplies themselves. Also, as used herein, an expression indicating that sizes such as widths are identical, like the “same wiring width,” is to be understood as including a range of manufacturing variations.

### Embodiment

### <Inverter Cell>

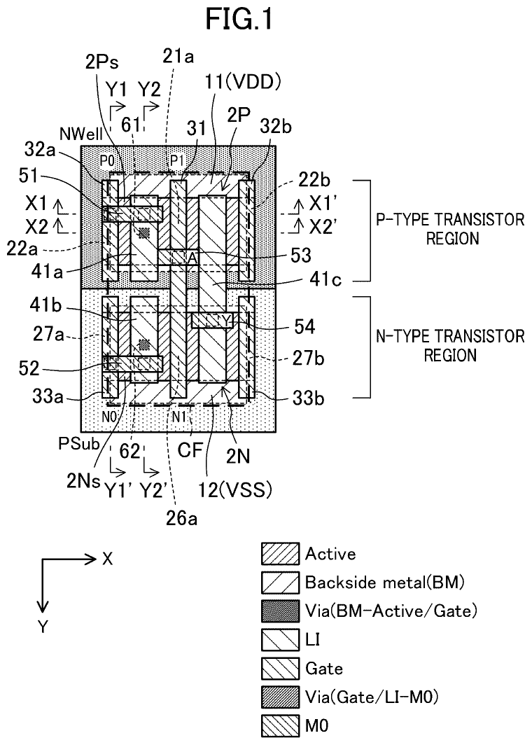

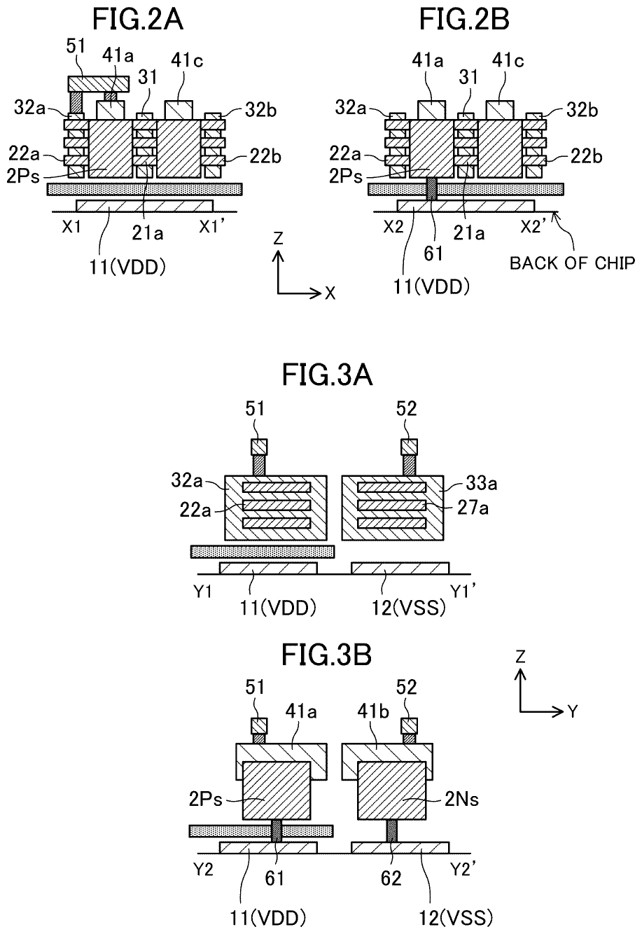

FIGS. 1, 2A-2B, and 3A-3B are views showing an example of the layout structure of an inverter cell included in a semiconductor integrated circuit device according to an embodiment, where FIG. 1 is a plan view, FIGS. 2A and 2B are cross-sectional views taken horizontally in planar view, and FIGS. 3A and 3B are cross-sectional views taken vertically in planar view. Specifically, FIG. 2A shows a cross section taken along line X1-X1′, FIG. 2B shows a cross section taken along line X2-X2′, FIG. 3A shows a cross section taken along line Y1-Y1′, and FIG. 3B shows a cross section taken along line Y2-Y2′.

Note that, in the plan views such as FIG. 1, the horizontal direction in the figure is hereinafter referred to as an X direction (corresponding to the first direction), the vertical direction in the figure as a Y direction (corresponding to the second direction), and the direction perpendicular to the substrate plane as a Z direction.

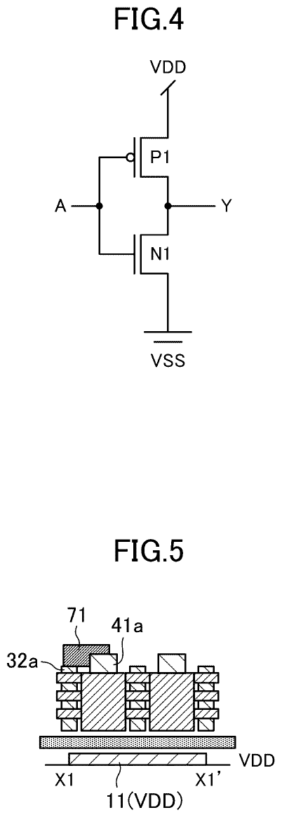

FIG. 4 is a circuit diagram of the inverter cell shown in FIGS. 1, 2A-2B, and 3A-3B. As shown in FIG. 4, the inverter cell has a p-type transistor P1 and an n-type transistor N1.

The inverter cell of FIGS. 1, 2A-2B, and 3A-3B and other standard cells are arranged in line in the X direction with the cell frame CF of each cell being in contact with adjacent ones, thereby constituting a cell row. A plurality of such cell rows are arranged in the Y direction with the cell frame CF being in contact with adjacent ones. Note that such cell rows are flipped vertically every other row.

Power lines 11 and 12 extending in the X direction are formed in an interconnect layer provided on the back of the semiconductor chip in which the transistors are formed. The power line 11 supplies the power supply voltage VDD, and the power line 12 supplies the power supply voltage VSS. The power lines 11 and 12 are shared with other cells in the cell row including the inverter cell, to serve as power lines extending in the X direction. Also, each of the power lines 11 and 12 is shared with a cell row adjacent in the Y direction.

In a p-type transistor region on an n-type well (NWell), an active region 2P forming the channel, source, and drain of the p-type transistor is formed. The active region 2P overlaps the power line 11 in planar view.

In the p-type transistor region, the p-type transistor P1 is formed. The transistor P1 has nanosheets 21a of a structure of three sheets lying one above another and extending in the X direction. That is, the transistor P1 is a nanosheet FET. In the active region 2P, a portion (region 2Ps) that is to be the source of the transistor P1 is connected to the power supply 11 through a via 61.

Also, the active region 2P is contiguous with nanosheets 22a and 22b formed on the side portions of the cell frame CF in the X direction. Like the nanosheets 21a, the nanosheets 22a and 22b have a structure of three sheets lying one above another and extending in the X direction. The nanosheets 22a are shared with a cell adjacent on the left in the figure, and the nanosheets 22b are shared with a cell adjacent on the right in the figure. Since the nanosheets 22a and 22b are formed on the cell frame CF, the active region 2P is to be formed continuously in the cell row constituted by a plurality of cells arranged in the X direction. In this way, a plurality of p-type nanosheet FETs can be formed without discontinuities.

In an n-type transistor region on a p-type substrate (Psub), an active region 2N forming the channel, source, and drain of the n-type transistor is formed. The active region 2N overlaps the power line 12 in planar view. Note that the n-type transistor region may be formed on a p-type well.

In the n-type transistor region, the n-type transistor N1 is formed. The transistor N1 has nanosheets 26a of a structure of three sheets lying one above another and extending in the X direction. That is, the transistor N1 is a nanosheet FET. In the active region 2N, a portion (region 2Ns) that is to be the source of the transistor N1 is connected to the power supply 12 through a via 62.

Also, the active region 2N is contiguous with nanosheets 27a and 27b formed on the side portions of the cell frame CF in the X direction. Like the nanosheets 26a, the nanosheets 27a and 27b have a structure of three sheets lying one above another and extending in the X direction. The nanosheets 27a are shared with a cell adjacent on the left in the figure, and the nanosheets 27b are shared with a cell adjacent on the right in the figure. Since the nanosheets 27a and 27b are formed on the cell frame CF, the active region 2N is to be formed continuously in the cell row constituted by a plurality of cells arranged in the X direction. In this way, a plurality of n-type nanosheet FETs can be formed without discontinuities.

Note that, in the active regions, the portions that are to be the sources and the drains on both sides of the nanosheets are formed by epitaxial growth from the nanosheets.

A gate interconnect 31 is formed to extend in the Y direction from the p-type transistor region over to the n-type transistor region. The gate interconnect 31 surrounds the peripheries of the nanosheets 21a of the transistor P1 and the nanosheets 26a of the transistor N1 in the Y and Z directions via gate insulating films (not shown). The gate interconnect 31 corresponds to the gates of the transistors P1 and N1.

In the p-type transistor region, dummy gate interconnects 32a and 32b are formed on the side portions of the cell frame CF in the X direction. The dummy gate interconnect 32a surrounds the peripheries of the nanosheets 22a in the Y and Z directions via gate insulating films (not shown). The dummy gate interconnect 32b surrounds the peripheries of the nanosheets 22b in the Y and Z directions via gate insulating films (not shown).

In the n-type transistor region, dummy gate interconnects 33a and 33b are formed on the side portions of the cell frame CF in the X direction. The dummy gate interconnect 33a surrounds the peripheries of the nanosheets 27a in the Y and Z directions via gate insulating films (not shown). The dummy gate interconnect 33b surrounds the peripheries of the nanosheets 27b in the Y and Z directions via gate insulating films (not shown).

The dummy gate interconnects 32a and 33a are shared with the cell placed on the left in the figure, and the dummy gate interconnects 32b and 33b are shared with the cell placed on the right in the figure.

Local interconnects 41a, 41b, and 41c extending in the Y direction are formed in a local interconnect layer. The local interconnect 41a is connected to the region 2Ps in the active region 2P. The local interconnect 41b is connected to the region 2Ns in the active region 2N.

The local interconnect 41c, extending from the p-type transistor region over to the n-type transistor region, is connected to a portion that is to be the drain of the transistor P1 in the active region 2P and a portion that is to be the drain of the transistor N1 in the active region 2N.

Metal interconnects 51, 52, 53, and 54 extending in the X direction are formed in an M0 interconnect layer that is a metal interconnect layer located above the local interconnect layer. The metal interconnect 51 is connected to the local interconnect 41a through a via, and also connected to the dummy gate interconnect 32a through a via. The metal interconnect 52 is connected to the local interconnect 41b through a via, and also connected to the dummy gate interconnect 33a through a via. The metal interconnect 53 is connected to the gate interconnect 31 through a via. The metal interconnect 54 is connected to the local interconnect 41c through a via. The metal interconnect 53 corresponds to a node A, and the metal interconnect 54 corresponds to a node Y.

In the inverter cell shown in FIGS. 1, 2A-2B, and 3A-3B, the via 61 is placed at a position overlapping, in planar view, the region 2Ps that is to be the source of the transistor P1 in the active region 2P. The via 61 connects the region 2Ps and the power line 11 formed on the back of the semiconductor chip, whereby VDD is supplied to the region 2Ps. Also, the local interconnect 41a is connected to the region 2Ps, and the dummy gate interconnect 32a on the cell frame CF is connected to the local interconnect 41a through the M0 interconnect 51, whereby VDD is supplied to the dummy gate interconnect 32a. The region 2Ps is adjacent to the dummy gate interconnect 32a and the nanosheets 22a in planar view.

Also, in the active region 2N, the via 62 is placed at a position overlapping, in planar view, the region 2Ns that is to be the source of the transistor N1. The via 62 connects the region 2Ns and the power line 12 formed on the back of the semiconductor chip, whereby VSS is supplied to the region 2Ns. Also, the local interconnect 41b is connected to the region 2Ns, and the dummy gate interconnect 33a on the cell frame CF is connected to the local interconnect 41b through the M0 interconnect 52, whereby VSS is supplied to the dummy gate interconnect 33a. The region 2Ns is adjacent to the dummy gate interconnect 33a and the nanosheets 27a in planar view.

Since VDD is supplied to the dummy gate interconnect 32a, a transistor P0 having the nanosheets 22a is an off transistor, having no influence on the logical operation of the semiconductor integrated circuit device. Also, since VSS is supplied to the dummy gate interconnect 33a, a transistor NO having the nanosheets 27a is an off transistor, having no influence on the logical operation of the semiconductor integrated circuit device.

While the power lines 11 and 12 are formed in the interconnect layer provided on the back of the semiconductor chip, the configuration is not limited to this. According to the present disclosure, it is only required for the power lines to be formed on the back side of the transistors. The “back side of the transistors” as used herein refers to the side, with respect to the transistors, opposite to the side on which the local interconnects, the metal interconnects, and the like connected to the transistors are stacked one upon another.

Also, the power lines 11 and 12 may be formed in a plurality of interconnect layers.

### Other Configuration Example 1

FIG. 5 is a view showing another configuration example, which is a cross-sectional view taken along the horizontal line X1-X1′ in planar view in FIG. 1. In the configuration of FIG. 5, the dummy gate interconnect 32a is connected to the local interconnect 41a through a contact 71 (shared contact), in place of the MO interconnect 51 and the vias. Similarly to the configuration of FIG. 5, the dummy gate interconnect 33a may be connected to the local interconnect 41b through a shared contact, in place of the MO interconnect 52 and the vias.

### Other Configuration Example 2

The power lines on the back side of the transistors described above may also be formed using a semiconductor chip other than the semiconductor chip in which the transistors are formed.

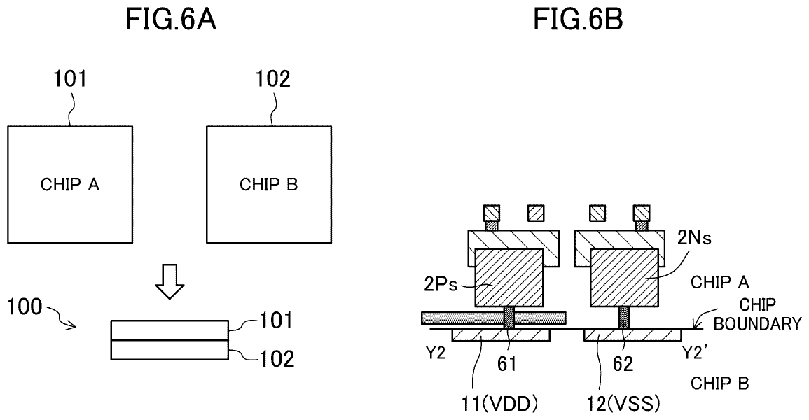

FIG. 6A shows yet another configuration example of the semiconductor integrated circuit device according to the embodiment. A semiconductor integrated circuit device 100 shown in FIG. 6A is constituted by a first semiconductor chip 101 (chip A) and a second semiconductor chip 102 (chip B) stacked one upon the other. In the chip A, standard cells including the above-described inverter cell and the like are placed. In the chip B, power lines are formed in an interconnect layer provided on the surface. The chip B is bonded to the back of the chip A using bumps and the like.

FIG. 6B shows a cross section of this configuration example taken along line Y2-Y2′ in the inverter cell of FIG. 1. As shown in FIG. 6B, the power line 11 supplying VDD and the power line 12 supplying VSS are formed in the interconnect layer provided on the surface of the chip B. The power line 11 is connected to the region 2Ps in the chip A through the via 61, and the power line 12 is connected to the region 2Ns in the chip A through the via 62.

With this configuration example, also, effects similar to those in the inverter cell described above can be obtained. Note that, in this configuration example, also, the power lines 11 and 12 may be formed in a plurality of interconnect layers.

### <2-Input NAND Cell and 2-Input NOR Cell>

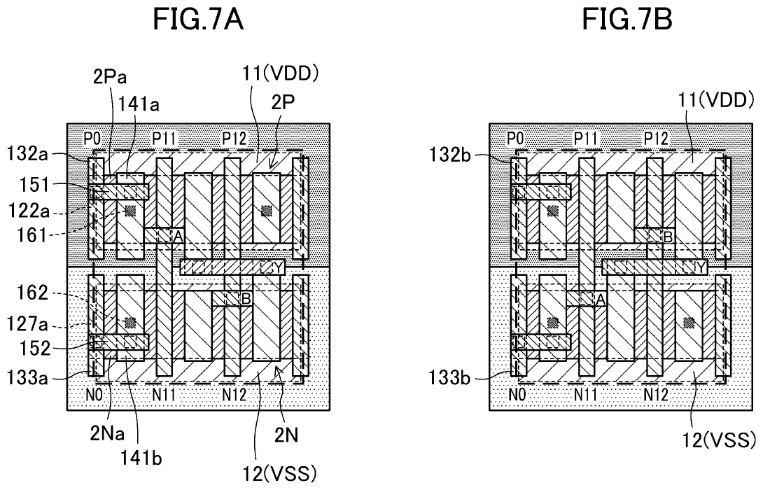

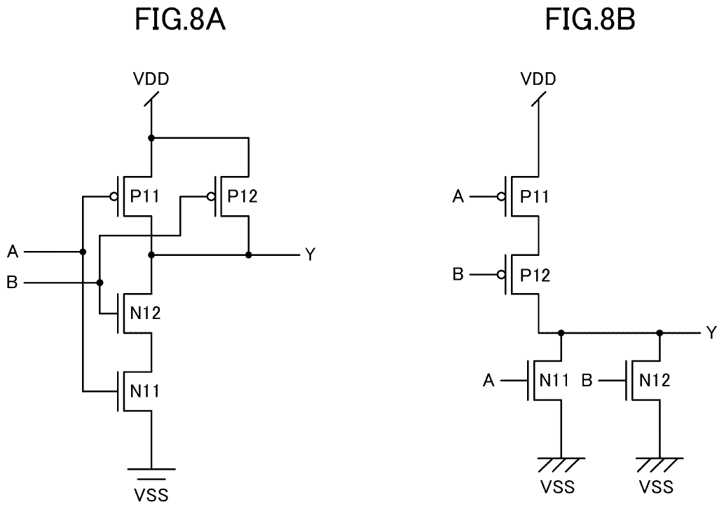

FIGS. 7A-7B are plan views showing layout structure examples of cells included in the semiconductor integrated circuit device according to the embodiment, where FIG. 7A shows a 2-input NAND cell and FIG. 7B shows a 2-input NOR cell. FIG. 8A is a circuit diagram of the 2-input NAND cell, and FIG. 8B is a circuit diagram of the 2-input NOR cell. Note that, for the layout structures of FIGS. 7A-7B, description of configurations that can be easily known by analogy from the above description on the inverter cells and the circuit diagrams of FIGS. 8A-8B may be omitted or simplified.

In the configuration of FIG. 7A, in the active region 2P, a via 161 is placed at a position overlapping, in planar view, a portion (region 2Pa) that is to be the source of a transistor P11. The region 2Pa is adjacent to nanosheets 122a and a dummy gate interconnect 132a that are formed on the cell frame CF. The via 161 connects the region 2Pa and the power line 11 formed on the back of the semiconductor chip, whereby VDD is supplied to the region 2Pa. Also, a local interconnect 141a is connected to the region 2Pa, and the dummy gate interconnect 132a is connected to the local interconnect 141a through an MO interconnect 151, whereby VDD is supplied to the dummy gate interconnect 132a. Therefore, a transistor PO having the nanosheets 122a is an off transistor, having no influence on the logical operation of the semiconductor integrated circuit device.

Also, in the active region 2N, a via 162 is placed at a position overlapping, in planar view, a portion (region 2Na) that is to be the source of a transistor N11. The region 2Na is adjacent to nanosheets 127a and a dummy gate interconnect 133a that are formed on the cell frame CF. The via 162 connects the region 2Na and the power line 12 formed on the back of the semiconductor chip, whereby VSS is supplied to the region 2Na. Also, a local interconnect 141b is connected to the region 2Na, and the dummy gate interconnect 133a is connected to the local interconnect 141b through an MO interconnect 152, whereby VSS is supplied to the dummy gate interconnect 133a. Therefore, a transistor NO having the nanosheets 127a is an off transistor, having no influence on the logical operation of the semiconductor integrated circuit device.

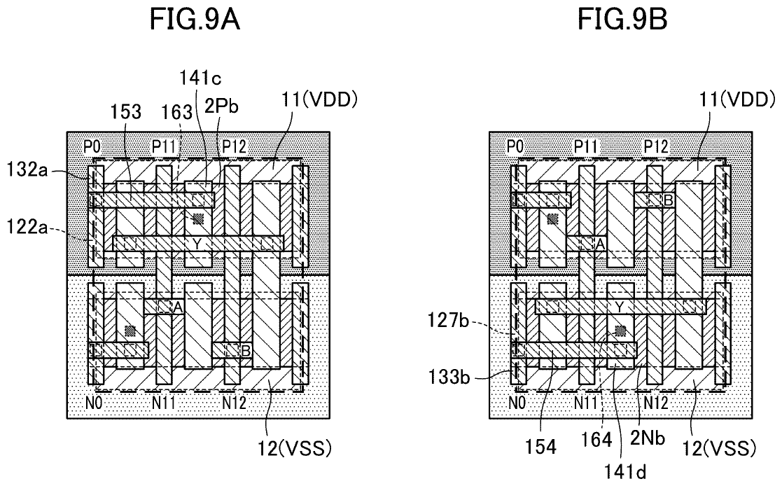

In the configuration of FIG. 7B, also, VDD is supplied to a dummy gate interconnect 132b and VSS is supplied to a dummy gate interconnect 133b. Therefore, transistors PO and N0 formed on the left portion of the cell frame CF in the figure are off transistors, having no influence on the logical operation of the semiconductor integrated circuit device. FIGS. 9A-9B are plan views showing alterations of the configurations of FIGS. 7A-7B, where FIG. 9A shows a 2-input NAND cell and FIG. 9B shows a 2-input NOR cell.

In the configuration of FIG. 9A, the dummy gate interconnect 132a is connected to a portion (region 2Pb) that is to be the sources of transistors P11 and P12 in the active region 2P. The region 2Pb, located between the transistors P11 and P12, is apart from the nanosheets 122a and the dummy gate interconnect 132a that are formed on the cell frame CF. A via 163 is placed at a position overlapping the region 2Pb in planar view, to connect the region 2Pb and the power line 11 formed on the back of the semiconductor chip. A local interconnect 141c is connected to the region 2Pb, and the dummy gate interconnect 132a is connected to the local interconnect 141c through an M0 interconnect 153, whereby VDD is supplied to the dummy gate interconnect 132a.

In the configuration of FIG. 9B, the dummy gate interconnect 133b is connected to a portion (region 2Nb) that is to be the sources of transistors N11 and N12 in the active region 2N. The region 2Nb, located between the transistors N11 and N12, is apart from nanosheets 127b and the dummy gate interconnect 133b that are formed on the cell frame CF. A via 164 is placed at a position overlapping the region 2Nb in planar view, to connect the region 2Nb and the power line 12 formed on the back of the semiconductor chip. A local interconnect 141d is connected to the region 2Nb, and the dummy gate interconnect 133b is connected to the local interconnect 141d through an MO interconnect 154, whereby VSS is supplied to the dummy gate interconnect 133b.

### <Buffer Cell>

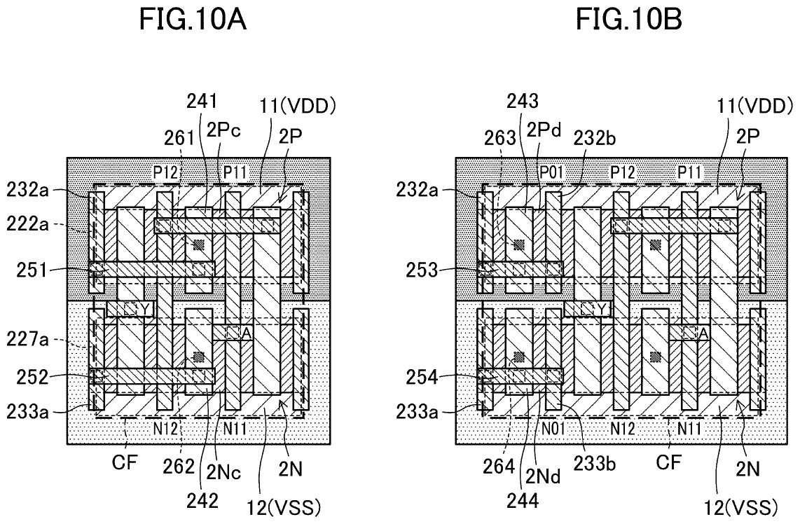

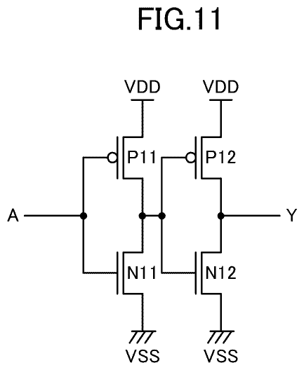

FIGS. 10A-10B are plan views showing layout structure examples of buffer cells included in the semiconductor integrated circuit device according to the embodiment. FIG. 11 is a circuit diagram of the buffer cells. Note that, for the layout structures of FIGS. 10A-10B, description of configurations that can be easily known by analogy from the above description on the various cells and the circuit diagram of FIG. 11 may be omitted or simplified.

In the configuration of FIG. 10A, a dummy gate interconnect 232a is connected to a portion (region 2Pc) that is to be the sources of transistors P11 and P12 in the active region 2P. The region 2Pc, located between the transistors P11 and P12, is apart from nanosheets 222a and the dummy gate interconnect 232a that are formed on the cell frame CF. A via 261 is placed at a position overlapping the region 2Pc in planar view, to connect the region 2Pc and the power line 11 formed on the back of the semiconductor chip. A local interconnect 241 is connected to the region 2Pc, and the dummy gate interconnect 232a is connected to the local interconnect 241 through an M0 interconnect 251, whereby VDD is supplied to the dummy gate interconnect 232a.

Also, in the configuration of FIG. 10A, a dummy gate interconnect 233a is connected to a portion (region 2Nc) that is to be the sources of transistors N11 and N12 in the active region 2N. The region 2Nc, located between the transistors N11 and N12, is apart from nanosheets 227a and the dummy gate interconnect 233a that are formed on the cell frame CF. A via 262 is placed at a position overlapping the region 2Nc in planar view, to connect the region 2Nc and the power line 12 formed on the back of the semiconductor chip. A local interconnect 242 is connected to the region 2Nc, and the dummy gate interconnect 233a is connected to the local interconnect 242 through an MO interconnect 252, whereby VSS is supplied to the dummy gate interconnect 233a.

FIG. 10B shows an alteration of the configuration of FIG. 10A. In the configuration of FIG. 10B, a dummy transistor P01 including a dummy gate interconnect 232b is formed on the left side of the transistor P12 in the figure, and a dummy transistor N01 including a dummy gate interconnect 233b is formed on the left side of the transistor N12 in the figure.

In the active region 2P, a region 2Pd located between the dummy gate interconnects 232a and 232b is a region that is to be the source or drain of the dummy transistor P01 constituting no logic circuit, and therefore does not contribute to the circuit operation. A via 263 is placed at a position overlapping the region 2Pd in planar view, to connect the region 2Pd and the power line 11. A local interconnect 243 is connected to the region 2Pd, and the dummy gate interconnects 232a and 232b are connected to the local interconnect 243 through an M0 interconnect 253, whereby VDD is supplied to the dummy gate interconnects 232a and 232b.

In the active region 2N, a region 2Nd located between the dummy gate interconnects 233a and 233b is a region that is to be the source or drain of the dummy transistor N01 constituting no logic circuit, and therefore does not contribute to the circuit operation. A via 264 is placed at a position overlapping the region 2Nd in planar view, to connect the region 2Nd and the power line 12. A local interconnect 244 is connected to the region 2Nd, and the dummy gate interconnects 233a and 233b are connected to the local interconnect 244 through an M0 interconnect 254, whereby VSS is supplied to the dummy gate interconnects 233a and 233b.

In the alteration of FIG. 10B, the regions 2Pd and 2Nd, which are to be the sources or drains of the dummy transistors P01 and N01 constituting no logic circuit and do not contribute to the circuit operation, are used for fixing the potentials of the dummy gate interconnects 232a and 233a located on the cell frame CF. It is therefore possible to reduce the influence of a cell adjacent to the buffer cell on the left in the X direction on the operation characteristics of the buffer cell.

### <Double-Height Cell>

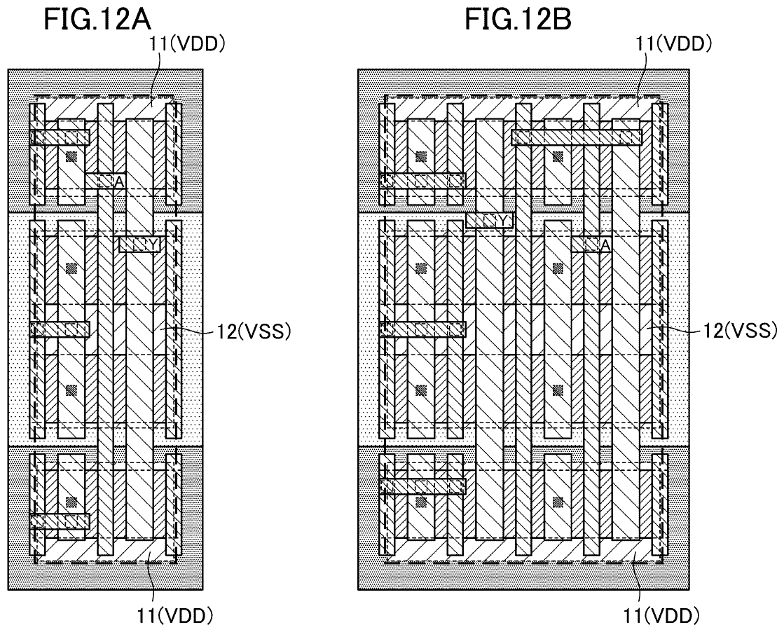

FIGS. 12A-12B are plan views showing layout structure examples of double-height cells included in the semiconductor integrated circuit device according to the embodiment, where FIG. 12A shows an inverter cell and FIG. 12B shows a buffer cell.

The double-height cell of FIG. 12A is based on a configuration in which an inverter cell vertically flipped from the inverter cell of FIG. 1 is adjacent to the inverter cell of FIG. 1 on the bottom side in the figure. The double-height cell of FIG. 12B is based on a configuration in which a buffer cell vertically flipped from the buffer cell of FIG. 10B is adjacent to the buffer cell of FIG. 10B on the lower side in the figure. Note that, in the configurations of FIGS. 12A and 12B, as for MO interconnects, unnecessary ones are omitted and positions of some interconnects are changed.

### (Alteration)

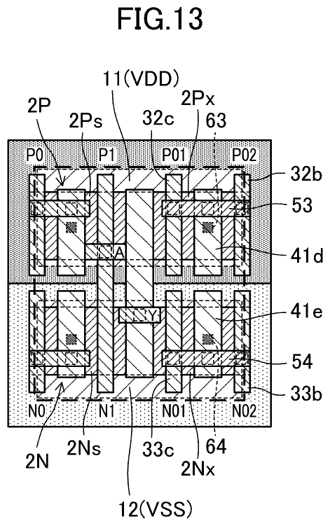

FIG. 13 shows an alteration of the configuration of the inverter cell of FIG. 1. In the configuration of FIG. 13, a dummy transistor P01 including a dummy gate interconnect 32c is placed on the right side of the transistor P1 in the X direction in the figure, and a dummy transistor N01 including a dummy gate interconnect 33c is placed on the right side of the transistor N1 in the X direction in the figure.

In the active region 2P, a region 2Px located between the dummy gate interconnects 32b and 32c is a region that is to be the source or drain of the dummy transistor P01 constituting no logic circuit, and therefore does not contribute to the circuit operation. A via 63 is placed at a position overlapping the region 2Px in planar view, to connect the region 2Px and the power line 11. A local interconnect 41d is connected to the region 2Px, and the dummy gate interconnects 32b and 32c are connected to the local interconnect 41d through an MO interconnect 53, whereby VDD is supplied to the dummy gate interconnects 32b and 32c.

In the active region 2N, a region 2Nx located between the dummy gate interconnects 33b and 33c is a region that is to be the source or drain of the dummy transistor N01 constituting no logic circuit, and therefore does not contribute to the circuit operation. A via 64 is placed at a position overlapping the region 2Nx in planar view, to connect the region 2Nx and the power line 12. A local interconnect 41e is connected to the region 2Nx, and the dummy gate interconnects 33b and 33c are connected to the local interconnect 41e through an MO interconnect 54, whereby VSS is supplied to the dummy gate interconnects 33b and 33c.

In the configuration of FIG. 13, since VDD is supplied to the dummy gate interconnect 32b, a transistor P02 located on the cell frame CF is an off transistor, having no influence on the logical operation of the semiconductor integrated circuit device. Also, since VSS is supplied to the dummy gate interconnect 33b, a transistor N02 located on the cell frame CF is an off transistor, having no influence on the logical operation of the semiconductor integrated circuit device. That is, in the configuration of FIG. 13, the transistors P0, P02, N0, and N02 located on the side portions of the cell frame CF in the X direction are all off transistors.

In the configurations such as in FIG. 1, the transistors on the left portion of the cell frame CF can be put in the off state. Therefore, in a cell row constituted by cells arranged in the X direction with no flipping, it is somehow possible to put transistors located on all cell boundaries in the off state. However, since this does not allow any cell to be flipped in the X direction, large restrictions are to be imposed on the placement of cells. By contrast, in the configuration according to this alteration, since both transistors on the left and right portions of the cell frame CF can be put in the off state, no problem will occur when cells are flipped in the X direction in the formation of a cell row. This alteration can therefore enhance the degree of freedom of cell placement.

Note that, while the alteration of the inverter cell has been described above, similar configurations are also applicable to the other types of cells described above, in which transistors on both side portions of the cell frame CF in the X direction can be put in the off state.

### <Filler Cell>

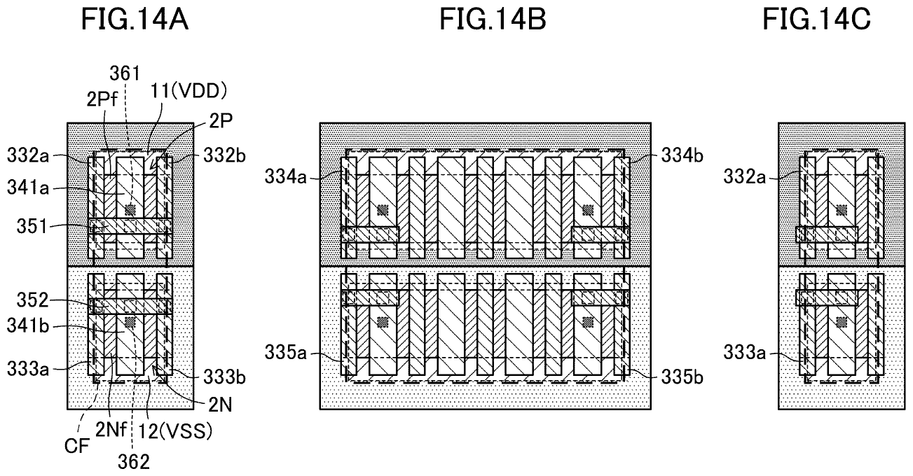

FIGS. 14A to 14C are layout structure examples of filler cells included in the semiconductor integrated circuit device according to the embodiment. The filler cells are cells for filling spaces between logic cells. FIG. 14A shows a configuration example of a filler cell having a cell width of 1 grid, and FIG. 14B shows a configuration example of a filler cell having a cell width of 4 grids. Note that the grid as used herein refers to a virtual line used for placement of components at design time, and also indicates the spacing between the lines. For example, in this case, it is assumed that the gate interconnects are placed on the grids. FIG. 14C is an alteration of the configuration of FIG. 14A.

In the configuration of FIG. 14A, in the p-type transistor region, dummy gate interconnects 332a and 332b are formed on the side portions of the cell frame CF in the X direction. A region 2Pf located between the dummy gate interconnects 332a and 332b in the active region 2P is connected to the power line 11 through a via 361. A local interconnect 341a is connected to the region 2Pf, and the dummy gate interconnects 332a and 332b are connected to the local interconnect 341a through an M0 interconnect 351, whereby VDD is supplied to the dummy gate interconnects 332a and 332b.

In the n-type transistor region, dummy gate interconnects 333a and 333b are formed on the side portions of the cell frame CF in the X direction. A region 2Nf located between the dummy gate interconnects 333a and 333b in the active region 2N is connected to the power line 12 through a via 362. A local interconnect 341b is connected to the region 2Nf, and the dummy gate interconnects 333a and 333b are connected to the local interconnect 341b through an MO interconnect 352, whereby VSS is supplied to the dummy gate interconnects 333a and 333b.

Since VDD is supplied to the dummy gate interconnects 332a and 332b and VSS is supplied to the dummy gate interconnects 333a and 333b, the transistors on the cell frame CF are all off transistors, having no influence on the logical operation of the semiconductor integrated circuit device.

In filler cells different in cell width, also, as in the configuration of FIG. 14A, all transistors on the cell frame CF can be off transistors. For example, in the configuration of FIG. 14B, VDD is supplied to dummy gate interconnects 334a and 334b and VSS is supplied to dummy gate interconnects 335a and 335b. Therefore, the transistors on the cell frame CF are all off transistors, having no influence on the logical operation of the semiconductor integrated circuit device.

Thus, the filler cell according to the embodiment can just be placed with its grid width changing in response to the space width between logic cells.

Note that, while the dummy gate interconnects on both side portions of the cell frame CF in the X direction are fixed to the power supply potentials in the configurations of FIGS. 14A and 14B, only dummy gate interconnects on either one side portion may be fixed to the power supply potentials. For example, in the configuration of FIG. 14C, only the dummy gate interconnects 332a and 333a formed on the left side portion of the cell frame CF in the X direction are fixed to the power supply potentials. It is also possible to fix only the dummy gate interconnects formed on the right side portion of the cell frame CF in the X direction to the power supply potentials.

Also, in the configurations of FIGS. 14A to 14C, the dummy gate interconnects on the cell frame CF are fixed to the power supply potentials in both the p-type transistor region and the n-type transistor region. However, in only the p-type transistor region, the dummy gate interconnects on the cell frame CF may be fixed to the power supply potential, i.e., VDD.

Alternatively, in only the n-type transistor region, the dummy gate interconnects on the cell frame CF may be fixed to the power supply potential, i.e., VSS.

### <Block Layout>

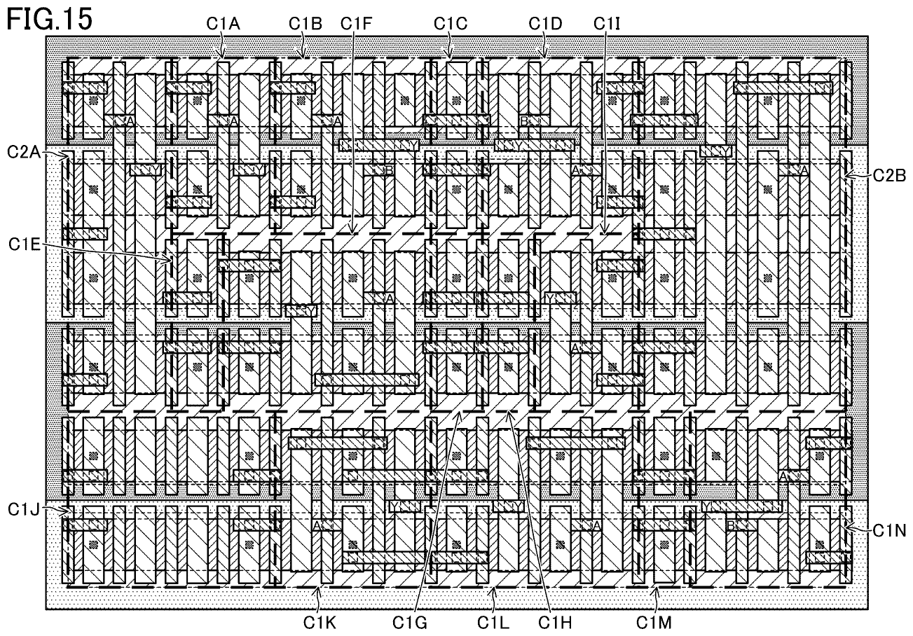

FIG. 15 is a plan view showing an example of the block layout of the semiconductor integrated circuit device according to the embodiment. The block layout of FIG. 15 includes three cell rows, and is configured by placing the cells described above. Cells C1A to C1N are single-height cells and cells C2A and C2B are double-height cells.

In the uppermost row, cells C2A, C1A, C1B, C1C, C1D, and C2B are placed in this order from left in the figure. The cell C2A is the inverter cell of FIGS. 12A, the cell C1A is the inverter cell of FIG. 1, the cell C1B is the 2-input NAND cell of FIG. 7A, the cell C1C is the filler cell of FIG. 14A, the cell C1D is a horizontally flipped one of the 2-input NOR cell of FIG. 7B, and the cell C2B is the buffer cell of FIG. 12B.

In the middle row, cells C2A, C1E, C1F, C1G, C1H, C1I, and C2B are placed in this order from left in the figure. The cell C1E is a vertically flipped one of the filler cell of FIG. 14A, the cell C1F is a vertically flipped one of the buffer cell of FIG. 10B, the cells C1G and C1H are vertically flipped ones of the filler cell of FIG. 14A, and the cell C1I is a vertically and horizontally flipped one of the inverter cell of FIG. 1.

In the lowermost row, cells C1J, C1K, C1L, C1M, and C1N are placed in this order from left in the figure. The cell C1J is the filler cell of FIG. 14B, the cell C1K is a horizontally flipped one of the buffer cell of FIG. 10A, the cell C1L is the buffer cell of FIG. 10B, the cell C1M is the filler cell of FIG. 14A, and the cell C1N is a horizontally flipped one of the 2-input NAND cell of FIG. 7A.

In the configuration of FIG. 15, the active regions are continuously formed in the X direction in each cell row, and all the dummy gate interconnects located on the cell boundaries are each supplied with the power supply potential VDD or VSS from at least one of the cells on both sides. As a result, transistors constituted by the dummy gate interconnects located on the cell boundaries are off transistors, having no influence on the logical operation of the circuits.

For example, the dummy gate interconnects located on the cell boundary between the cells C2A and C1A are supplied with VDD or VSS from the cell C1A on the right. Also, the dummy gate interconnects located on the cell boundary between the cells C1C and C1D are supplied with VDD or VSS from the cell C1C on the left. Since the cell C1D is horizontally flipped, the filler cell supplying power to dummy gate interconnects on both sides, i.e., the cell C1C, is placed on the left side of the cell C1D.

Also, the dummy gate interconnects located on the cell boundary between the cells C1E and C1F are supplied with VDD or VSS from the cell C1F on the right. The cell C1F is a vertically flipped one of the buffer cell of FIG. 10B, in which, as described above, the potentials of the dummy gate interconnects on the cell boundary are fixed using the regions that do not contribute to the circuit operation in the active regions. It is therefore possible to reduce the influence of the cell C1E on the operation characteristics of the cell C1F.

As described above, according to this embodiment, in the semiconductor integrated circuit device, a plurality of standard cells are arranged adjacently in the X direction. Each standard cell includes an active region forming the channel, source, and drain of a transistor and a power line formed on the back side of the transistor. Nanosheets that are contiguous with the active region are formed on the boundary between standard cells. Therefore, since the active region is continuous over a plurality of standard cells, a plurality of nanosheet FETs can be formed without discontinuities. A first region that is to be the source or the drain in the active region is connected to a power line through a via. A gate interconnect formed on the boundary between standard cells is electrically connected to the first region, to be supplied with the power supply voltage. In this way, the transistor constituted by the gate interconnect and the nanosheets on the boundary between standard cells is an off transistor, having no influence on the circuit operation of the semiconductor integrated circuit device.

Therefore, in the semiconductor integrated circuit device having interconnects provided right under transistors, it is possible to implement a layout structure in which a nanosheet FET having no influence on the circuit operation is formed between adjacent standard cells.

While the nanosheets have the structure of three sheets lying one above another and the cross-sectional shape of the sheet structure is illustrated as a rectangle in the above embodiment, the number of nanosheets, and the cross-sectional shape, of the sheet structure are not limited to these.

While nanosheet FETs are used as the transistors in the above embodiment, the type of the transistors is not limited to this. For example, fin FETs or other types of transistors may be used.

According to the present disclosure, in a semiconductor integrated circuit device having interconnects provided right under transistors, a layout structure that improves manufacturing precision, reduces manufacturing variations, and improves yield is presented. The present disclosure is therefore useful for cost reduction, and improvement in the performance, of a semiconductor integrated circuit device, for example.

1. A semiconductor integrated circuit device, comprising
first and second standard cells placed adjacently in a first direction, wherein
the first standard cell includes
a first active region forming a channel, source, and drain of a first transistor of a first conductivity type, including a nanosheet extending in the first direction as the channel,
a first power line supplying a first power supply voltage, formed on the back side of the first transistor, extending in the first direction, and having an overlap with the first active region in planar view, and
a first via formed at a position where a first region forming a source or a drain in the first active region and the first power line overlap each other, to connect the first region and the first power line,
a first nanosheet extending in the first direction and contiguous with the first active region and a first gate interconnect extending in a second direction perpendicular to the first direction and orthogonal to the first nanosheet in planar view are formed on a boundary between the first standard cell and the second standard cell, and
the first gate interconnect is electrically connected to the first region.

2. The semiconductor integrated circuit device of claim 1, wherein
the second standard cell includes a second active region forming a channel, source, and drain of a transistor of the first conductivity type, including a nanosheet extending in the first direction as the channel, and
the first nanosheet is contiguous with the second active region.

3. The semiconductor integrated circuit device of claim 1, wherein
the first gate interconnect is connected to the first region through a metal interconnect extending in the first direction.

4. The semiconductor integrated circuit device of claim 1, wherein
the first region is a region that is to be a source or drain of the first transistor that constitutes a logic circuit.

5. The semiconductor integrated circuit device of claim 1, wherein
the first region is a region that is to be a source or drain of the first transistor that does not constitute a logic circuit.

6. The semiconductor integrated circuit device of claim 1, wherein
the first region is adjacent to the first gate interconnect in planar view.

7. The semiconductor integrated circuit device of claim 1, wherein
the first region is apart from the first gate interconnect in planar view.

8. The semiconductor integrated circuit device of claim 1, wherein
the first power line is formed in an interconnect layer provided in a first semiconductor chip in which the first active region is formed.

9. The semiconductor integrated circuit device of claim 1, wherein
the first power line is formed in an interconnect layer provided in a second semiconductor chip bonded to the back of a first semiconductor chip in which the first active region is formed.

10. The semiconductor integrated circuit device of claim 1, further comprising
a third standard cell adjacent to the first standard cell on a side opposite to the second standard cell in the first direction,
wherein
a second nanosheet extending in the first direction and contiguous with the first active region and a second gate interconnect extending in the second direction and orthogonal to the second nanosheet in planar view are formed on a boundary between the first standard cell and the third standard cell,
the first standard cell includes
a second via formed at a position where a second region forming a source or a drain in the first active region and the first power line overlap each other, to connect the second region and the first power line, and
the second gate interconnect is electrically connected to the second region.

11. The semiconductor integrated circuit device of claim 1, wherein
the first standard cell includes
a second active region forming a channel, source, and drain of a second transistor of a second conductivity type, including a nanosheet extending in the first direction as the channel,
a second power line supplying a second power supply voltage, formed on the back side of the second transistor, extending in the first direction, and having an overlap with the second active region in planar view, and
a via formed at a position where a second region forming a source or a drain in the second active region and the second power line overlap each other, to connect the second region and the second power line,
a second nanosheet extending in the first direction and contiguous with the second active region and a second gate interconnect extending in the second direction and orthogonal to the second nanosheet in planar view are formed on a boundary between the first standard cell and the second standard cell, and
the second gate interconnect is electrically connected to the second region.
